(19) United States
(12) Patent Application Publication
(10) Pub. No.: US 2017/0288041 A1
(43) Pub. Date: Oct. 5, 2017

(54) METHOD FOR FORMING A DOPED REGION IN A FIN USING A VARIABLE THICKNESS SPACER AND THE RESULTING DEVICE

(71) Applicant: GLOBALFOUNDRIES Inc., Grand Cayman (KY)

(72) Inventors: Shesh Mani Pandey, Saratoga Springs, NY (US); Baofu Zhu, Clifton Park, NY (US); Francis Benistant, Singapore (SG)

(21) Appl. No.: 15/091,256

(22) Filed: Apr. 5, 2016

(51) Int. Cl. H01L 29/66; H01L 29/78; H01L 21/02; H01L 29/06; H01L 21/265

(52) U.S. Cl. CPC H01L 29/66795; H01L 29/0649; H01L 21/26513; H01L 29/6656; H01L 29/66545; H01L 21/26586; H01L 21/0217; H01L 29/7851

(57) ABSTRACT

A method includes forming a fin in a semiconductor substrate. An isolation structure is formed adjacent the fin. A first portion of the fin extends above the isolation structure. A gate electrode is formed above the first portion of the fin. A fin spacer is formed on the first portion of the fin. The fin spacer covers less than 50% of a height of the first portion of the fin. An implantation process is performed in the presence of the fin spacer to form a doped region in the first portion of the fin.

### BACKGROUND OF THE INVENTION

### 1. FIELD OF THE INVENTION

The present disclosure generally relates to the fabrication of semiconductor devices, and, more particularly, to a method for forming a doped region in a fin using a variable thickness spacer and the resulting device.

### 2. DESCRIPTION OF THE RELATED ART

In modern integrated circuits, such as microprocessors, storage devices and the like, a very large number of circuit elements, especially transistors, are provided on a restricted chip area. Transistors come in a variety of shapes and forms, e.g., planar transistors, FinFET transistors, nanowire devices, etc. The transistors are typically either NMOS (NFET) or PMOS (PFET) type devices wherein the “N” and “P” designation is based upon the type of dopants used to create the source/drain regions of the devices. So-called CMOS (Complementary Metal Oxide Semiconductor) technology or products refers to integrated circuit products that are manufactured using both NMOS and PMOS transistor devices. Irrespective of the physical configuration of the transistor device, each device comprises drain and source regions and a gate electrode structure positioned above and between the source/drain regions. Upon application of an appropriate control voltage to the gate electrode, a conductive channel region forms between the drain region and the source region.

In some applications, fins for FinFET devices are formed such that the fin is vertically spaced apart from and above the substrate, with an isolation material positioned between the fin and the substrate. FIG. 1 is a perspective view of an illustrative prior art FinFET semiconductor device 100 that is formed above a semiconductor substrate 105. In this example, the FinFET device 100 includes three illustrative fins 110, a gate structure 115, sidewall spacers 120 and a gate cap 125. The gate structure 115 typically includes a layer of insulating material (not separately shown), e.g., a layer of high-k insulating material or silicon dioxide, and one or more conductive material layers (e.g., metal and/or polysilicon) that serve as the gate electrode for the device 100. The fins 110 have a three-dimensional configuration. The portions of the fins 110 covered by the gate structure 115 are the channel regions and the uncovered portions are the source/drain regions of the FinFET device 100. An isolation structure 130 is formed between the fins 110.

Various implant procedures are employed to define dopant profiles in the FinFET device 100. The three-dimensional structure of the FinFET device 100 provides unique issues regarding implantation efficacy. Spacers, such as the sidewall spacers 120, are used to tailor the dopant profiles. Although not illustrated in FIG. 1, portions of the spacers 120 are present on the sidewalls of the fins 110 during the implantation sequence. With an extension region implant, an increased dopant dose generally improves drive current. However, without the spacer 120 along the height of the fins 110, the extension implant dosage will increase in the base region of the fin. An increased dose in the base region of the fin can give rise to short channel effects.

The present disclosure is directed to various methods and resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming semiconductor devices. A method includes, among other things, forming a fin in a semiconductor substrate. An isolation structure is formed adjacent the fin. A first portion of the fin extends above the isolation structure. A gate electrode is formed above the first portion of the fin. A fin spacer is formed on the first portion of the fin. The fin spacer covers less than 50% of a height of the first portion of the fin. An implantation process is performed in the presence of the fin spacer to form a doped region in the first portion of the fin.

Another method includes forming a fin in a semiconductor substrate. An isolation structure is formed adjacent the fin. A first portion of the fin extends above the isolation structure. A gate insulation layer is formed above the first portion of the fin. A gate electrode is formed above the gate insulation layer. A spacer layer is formed above the gate electrode and the fin. The spacer layer is etched to define a fin spacer on the first portion of the fin and a gate spacer on the gate electrode. The fin spacer covers less than 50% of a height of the first portion of the fin. A tilted implantation process is performed in the presence of the fin spacer to form a doped region in the first portion of the fin.

A device includes a fin defined in a semiconductor substrate. An isolation structure is positioned adjacent the fin. A first portion of the fin extends above the isolation structure. A gate electrode is positioned above the first portion of the fin. A fin spacer is positioned on the first portion of the fin. The fin spacer covers less than 50% of a height of the first portion of the fin. A gate spacer is positioned on the gate electrode. A doped region is defined in the first portion of the fin. At least a portion of the doped region is positioned laterally adjacent the fin spacer.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically depicts an illustrative prior art finFET device; and

FIGS. 2A-2E depict various methods disclosed herein of forming a finFET device.

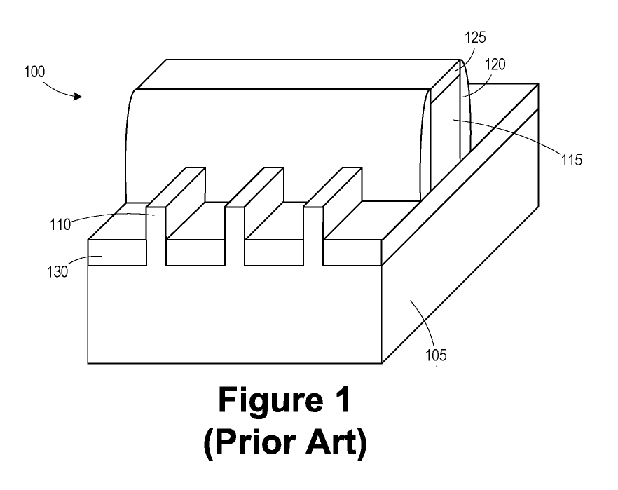

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of forming a doped region in a finFET device using a variable thickness spacer and the resulting semiconductor devices. As will be readily apparent to those skilled in the art upon a complete reading of the present application, the present method is applicable to a variety of devices, including, but not limited to, logic devices, memory devices, etc. With reference to the attached figures, various illustrative embodiments of the methods and devices disclosed herein will now be described in more detail.

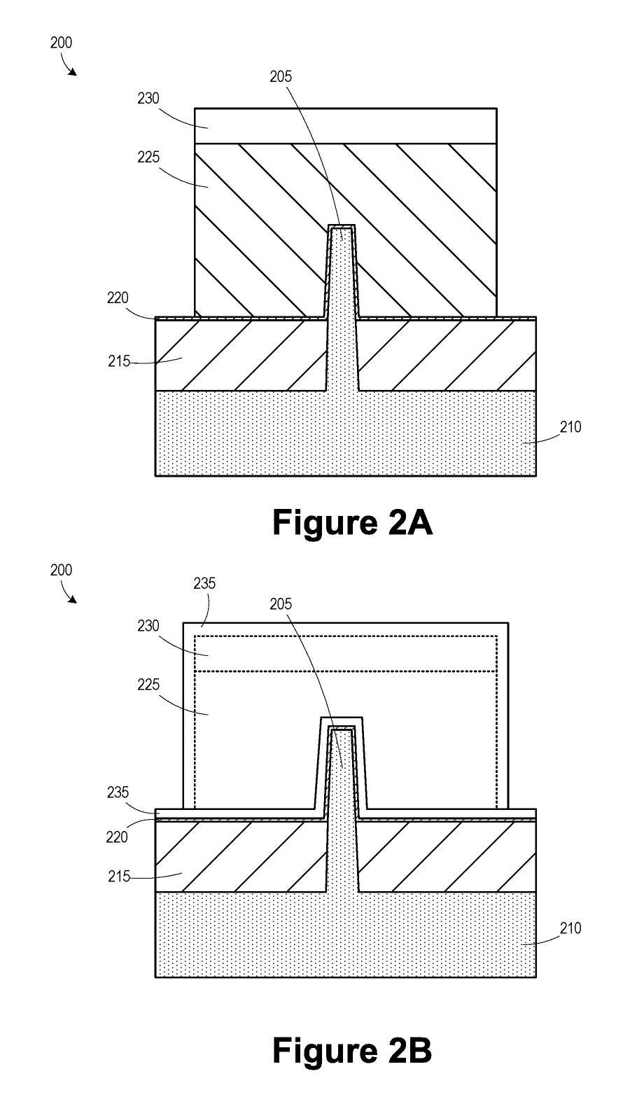

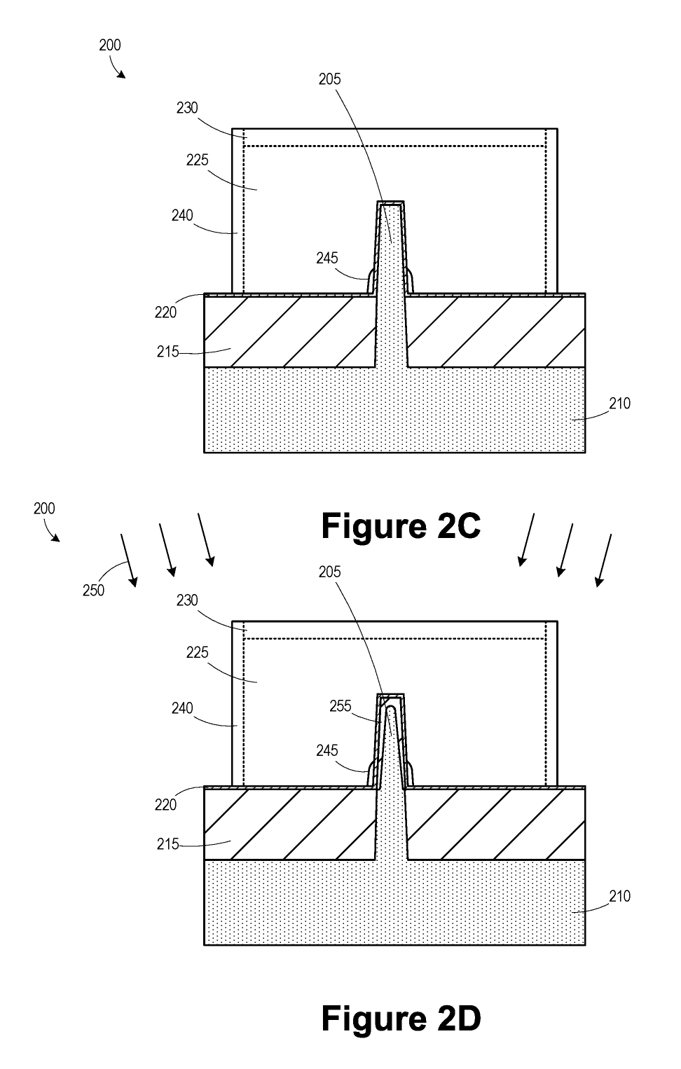

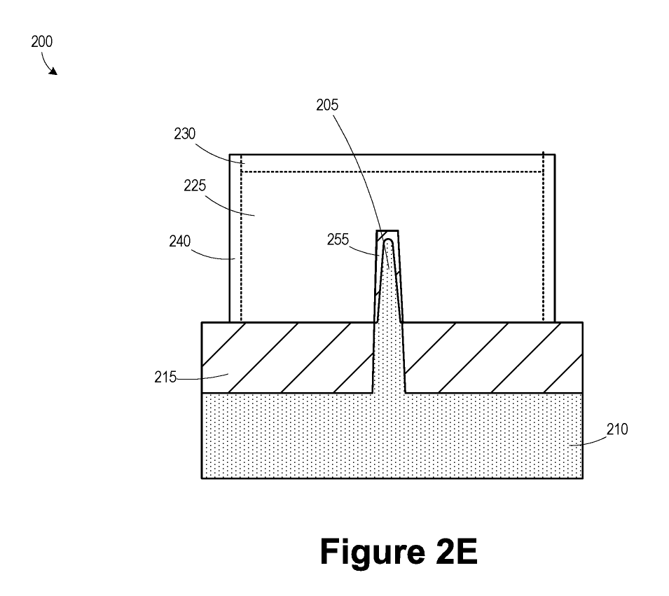

FIGS. 2A-2E illustrate various novel methods disclosed herein for forming an integrated circuit product 200. The product 200 includes at least one fin 205 defined in a substrate 210. An isolation structure 215 (e.g., silicon dioxide) is formed adjacent the fin 205. A gate insulation layer 220 (e.g., silicon dioxide or a high-k oxide) is formed above the fin 205 and the isolation structure 215. A placeholder gate electrode 225 (e.g., amorphous silicon) is formed above a portion of the fin 205 in a channel region of the product 200. A cap layer 230 is provided above the placeholder gate electrode 225. The cap layer 230 was patterned and an etch process was performed using the cap layer 230 as an etch mask to define the placeholder gate electrode 225. The gate insulation layer 220 was used as an etch stop layer when etching the placeholder gate electrode 225.

The views in FIGS. 2A-2E are a combination of a cross-sectional view taken across the fins 205 in the source/drain regions of the devices in a direction corresponding to the gate width direction of the device, and a side view of the placeholder gate electrode 225 prior to the formation of any sidewall spacers. The number of fins 205 and the spacing between fins may vary depending on the particular characteristics of the device(s) being formed. The substrate 210 may have a variety of configurations, such as the depicted bulk silicon configuration. The substrate 210 may also have a silicon-on-insulator (SOI) configuration that includes a bulk silicon layer, a buried insulation layer and an active layer, wherein semi-conductor devices are formed in and above the active layer. The substrate 210 may be formed of silicon or silicon germanium or it may be made of materials other than silicon, such as germanium. Thus, the terms “substrate” or “semiconductor substrate” should be understood to cover all semiconducting materials and all forms of such materials. The substrate 210 may have different layers. For example, the fin 205 may be formed in a process layer formed above a base layer of the substrate 210.

In one illustrative embodiment, a replacement gate technique is used to form the integrated circuit product 200, and the placeholder gate electrode 225 is illustrated prior to the formation of the replacement gate structure. However, the application of the present subject matter is not limited to a replacement gate or “gate-last” technique, but rather, a gate-first technique may also be used, and a conductive gate electrode material may be substituted for the material of the placeholder gate electrode 225.

FIG. 2B illustrates the integrated circuit product 200 after a deposition process was performed to form a spacer layer 235 (e.g., silicon nitride) above the placeholder gate electrode 225 and the fin 205. The placeholder gate electrode 225 and the gate cap layer 230 are shown in phantom. The relative thicknesses of the gate cap layer 230 and the spacer layer 235 may vary depending on the particular embodiment.

FIG. 2C illustrates the integrated circuit product 200 after an anisotropic etch process was performed to etch the spacer layer 235 to form a sidewall spacer 240 on the placeholder gate electrode 225. The spacer etch process also reduces the thickness of the cap layer 230. The spacer etch process is terminated prior to completely removing the spacer layer 235 on the sidewalls of the fin 205, thereby leaving fin spacers 245 that partially cover the sidewalls of the fin 205. In some embodiments, the spacer etch is timed so as to expose at least 50% of the portion of the fin 205 extending above the isolation structure 215 without completely removing the spacer layer 235. In FIG. 2C, approximately 75% of the fin 205 is exposed.

FIG. 2D illustrates the integrated circuit product 200 after a tilted implant process 250 (e.g., 15 degrees) was performed to define a doped region 255 in the fin 205. In the illustrated embodiment, the doped region 255 is an extension implant region. The spacer 245 allows an increased dopant dose to be used to increase drive current, while reducing the likelihood of introducing short channel effects by protecting the lower portion of the fin 205.

FIG. 2E illustrates the product after a plurality of processes were performed. A first etch process was performed to remove the spacers 245 and a second etch process was performed to remove the portions of the gate insulation layer 220 not covered by the placeholder gate electrode 225. In some embodiments, the spacers 245 may not be removed, thereby leaving a portion of the gate insulation layer 220 laterally adjacent and beneath the spacers 245.

Additional processes may be performed to complete the fabrication of the integrated circuit product 200, such as the formation of halo regions, source/drain regions, etc. Subsequent metallization layers and interconnect lines and vias may be formed. Other layers of material may be present, but are not depicted in the attached drawings.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A method, comprising:
forming a fin in a semiconductor substrate;
forming an isolation structure adjacent said fin, wherein a first portion of said fin extends above said isolation structure;
forming a gate insulation layer above said first portion of said fin;
forming a gate electrode above said gate insulation layer;
forming a spacer layer contacting said gate insulation layer on a second portion of said fin not covered by said gate electrode;
etching said spacer layer to define a fin spacer on said second portion of said fin and to expose a portion of said gate insulation layer disposed on an upper region of said second portion of said fin, wherein said fin spacer covers less than 70% of a height of said second portion of said fin; and
performing an implantation process in the presence of said fin spacer and said gate insulation layer on said upper region to form a doped region in said first portion of said fin.

2. The method of claim 1, wherein said fin spacer covers less than 50% of said height of said first portion of said fin.

3. The method of claim 1, wherein etching said spacer layer comprises etching said spacer layer to define a gate spacer on said gate electrode.

4. The method of claim 3, further comprising:
forming a cap layer above said gate electrode; and
forming said spacer layer above said cap layer.

5. The method of claim 4, wherein said cap layer and said spacer layer comprise silicon nitride.

6. The method of claim 1, wherein said fin spacer comprises silicon nitride.

7. The method of claim 1, wherein said gate electrode comprises a placeholder gate electrode.

8. The method of claim 7, wherein said placeholder gate electrode comprises amorphous silicon.

9. The method of claim 1, wherein said implantation process comprises a tilted implantation process.

10. -20. (canceled)

21. The method of claim 1, wherein said doped region comprises a doped extension region.

22. A method, comprising:
forming a fin in a semiconductor substrate;
forming an isolation structure adjacent said fin, wherein a first portion of said fin extends above said isolation structure;
forming a gate electrode above said first portion of said fin;
forming a fin spacer on said first portion of said fin, wherein said fin spacer covers less than 70% of a height of said first portion of said fin; and
performing a tilted implantation process in the presence of said fin spacer to form a doped extension region in said first portion of said fin.

23. The method of claim 22, wherein said fin spacer covers less than 50% of said height of said first portion of said fin.

24. The method of claim 23, further comprising:
forming a gate insulation layer above said first portion of said fin prior to forming said gate electrode;
forming a spacer layer above said gate insulation layer above a second portion of said fin not covered by said gate electrode; and
etching said spacer layer to define said fin spacer and a gate spacer on said gate electrode and to expose a portion of said gate insulation layer disposed on an upper region of said second portion of said fin, wherein said implantation process is performed in the presence of said fin spacer and said gate insulation layer on said upper region.

25. The method of claim 24, further comprising:
forming a cap layer above said gate electrode; and
forming said spacer layer above said cap layer.

26. The method of claim 25, wherein said cap layer and said spacer layer comprise silicon nitride.

27. The method of claim 22, wherein said fin spacer comprises silicon nitride.

28. The method of claim 22, wherein said gate electrode comprises a placeholder gate electrode.

29. The method of claim 28, wherein said placeholder gate electrode comprises amorphous silicon.
